(19) United States
(12) Patent Application Publication
(10) Pub. No.: US 2007/0114574 A1
(43) Pub. Date: May 24, 2007

(54) Semiconductor device

(76) Inventor: Hidekatsu Onose, Hitachi (JP)

Correspondence Address: MILES & STOCKBRIDGE PC, 1751 PINNACLE DRIVE, SUITE 500, MCLEAN, VA, 22102-3833, US

(21) Appl. No.: 11/599,356

(22) Filed: Nov. 15, 2006

(30) Foreign Application Priority Data
Nov. 16, 2005 (JP) 2005-331367

(51) Int. Cl. H01L 29/80

(52) U.S. Cl. 257/256

(57) ABSTRACT

An object of the present invention is to achieve both the high withstand voltage and the low on-resistance in a polycrystalline Si embedded gate SiC junction FET. n+ —SiC is formed as a drain layer; and n− —SiC which contacts an n+ drain layer is formed as a drift layer. By using n+ —SiC, which is formed on an n− drift layer, as a source layer, and by forming a trench from an n+ source layer up to a position having the specified depth of the n− drift layer, part of the n− drift layer is used as a channel region. As a result, in a junction FET including, as a gate region, p-type polycrystalline Si that is embedded in the trench, at least a side wall of the channel region contacts the p-type polycrystalline Si gate region without using oxidation film.

### CLAIM OF PRIORITY

The present application claims priority from Japanese application No. JP 2005-331367 filed on Nov. 16, 2005, the content of which is hereby incorporated by reference into this application.

### BACKGROUND OF THE INVENTION

1. Field of the Invention

The present invention relates to a structure of a junction FET (JFET) and that of a static induction transistor (SIT), and to a manufacturing method thereof.

2. Description of the Related Art

Since a dielectric breakdown field of silicon carbide (SiC) is about 10 times higher than that of Si, it is possible to form a thinner and higher-density drift layer for keeping the withstand voltage. Accordingly, SiC is a material capable of reducing a loss. As an example of JFET or SIT, which is one of power semiconductors that use SiC, there is a structure disclosed in Japanese Patent Application Laid-Open No. 2002-314096 (patent document 1). FIG. 2 is a diagram illustrating main elements of the structure. In the figure, reference numeral 10 denotes an n+ substrate that is a drain layer; reference numeral 11 denotes an n− drift layer; reference numeral 12 denotes an n+ source region; reference numeral 14 denotes a p gate region; and reference numerals 20, 21, 22 denote insulating film used to electrically insulate between the source and the gate.

In general, a p gate region 13 is formed by performing ion implantation of atoms such as Al into the n− drift layer 11. However, as far as SiC is concerned, since a diffusion coefficient of impurities is small, it is not possible to adopt thermal diffusion techniques that are usually applied to Si. For this reason, in order to form a pn junction having a deep box profile, multiple-step implantation which changes the implantation energy is required. As a result, there has been a disadvantage in that the process becomes complicated.

As a remedial measure for the above-described disadvantage, in the example shown in FIG. 2, a trench is formed on the n− drift layer 11, and then p-type polycrystalline Si is embedded in the trench to form the p gate region 14. This makes it possible to form a deep box profile without using the multiple-step ion implantation. Accordingly, it is possible to simplify the process.

Another feature of the structure shown in FIG. 2 is that an oxidation film is formed on the trench side wall 13, and accordingly a pn junction with the p gate region 14 is formed only on the bottom of the trench. In order to achieve a normally-off state in a JFET, it is necessary to cut off the contact between the n+ drain 10 and the n+source 12 by the expansion of a depletion layer with the gate voltage being kept at 0 V. Therefore, in FIG. 2, the channel layer 14 whose density is lower than that of the n− drift layer 11 is formed between the n− drift layer 11 and the n+ source 12 so that the depletion layer can easily extend. However, since the oxidation film 21 is formed on the trench side wall 13, the depletion layer extends only from the bottom surface of the trench. Therefore, in order to achieve, for example, a withstand voltage of 600 V, it is necessary to set the density of the channel layer 14 at the first half of 10¹⁵ cm⁻³ or lower, which results in an increase in on-resistance.

Patent document 1: Japanese Patent Application Laid-Open No. 2002-314096

### SUMMARY OF THE INVENTION

The main point of the problem to be solved is that it is not possible to achieve both the high withstand voltage and the low on-resistance in a SiC junction FET having a polycrystalline Si embedded gate.

The most important feature of the present invention is that a junction FET adopts a structure in which a trench side wall contacts polycrystalline Si at least in a channel region without using oxidation film.

Typical structures will be described as below.

To be more specific, according to one aspect of the present invention, there is provided a junction FET comprising:

a drain layer formed of first conductivity type SiC;

a drift layer formed of first conductivity type SiC whose impurity density is lower than that of the first conductivity type SiC forming the drain layer, the drift layer contacting the drain layer;

a source layer formed of first conductivity type SiC whose impurity density is higher than that of the first conductivity type SiC forming the drift layer, the source layer being formed on a surface of the drift layer which is opposite to the surface contacted with the drain layer;

a concave portion that is formed from the source layer up to the drift layer, the concave portion reaching the specified depth of a semiconductor layered product; and

a second conductivity type Si layer with which the concave portion is filled, the second conductivity type Si layer contacting each of both side walls of the semiconductor layered product ranging from the source layer up to the drift layer,

wherein:

the second conductivity type Si layer is a gate region; and

a channel region is formed in the drift layer.

In a practical mode, the second conductivity type Si layer which forms the gate region is a polycrystalline Si layer.

In addition, in another mode of the present invention which can be adopted, the Si gate region includes at least two regions, each of which has an impurity density different from that of other regions in a lamination direction. The density of the Si gate region contacting the side wall of the source region is lower than that of the other regions. The low-density Si gate region includes a high-density Si region located on the upper side of the semiconductor layered product in the lamination direction. This mode makes it possible to ensure the withstand voltage between the source and the gate, and to improve the normally-off performance.

The following mode is also useful for ensuring the high withstand voltage. More specifically, a second conductivity type SiC region is formed on the drift layer side of the second conductivity type Si layer that contacts the semiconductor layered product ranging from the source layer up to the drift layer.

There is provided still another useful mode in which a second conductivity type SiC region is formed on the drift layer side of the second conductivity type Si layer that contacts the semiconductor layered product ranging from the source layer up to the drift layer. In addition, there is provided a further useful mode in which a second conductivity type SiC region is formed on the drift layer side in the second conductivity type Si layer that contacts the semiconductor layered product ranging from the source layer up to the drift layer. Moreover, it is useful that an insulating film is formed between the side wall of the source region and the Si gate region to improve the withstand voltage between the source and the gate.

In the case where a plurality of FETs according to the present invention are provided on a single substrate, a first junction FET and a second junction FET include a metallic layer through which the second conductivity type Si layer of each of the junction FETs electrically connects a gate region on a specified substrate. This mode is practical. For example, this mode is applied to an inverter circuit.

According to the present invention, since a pn junction is formed on a side wall of a channel region in a JFET, a depletion layer extends throughout substantially the whole channel region. Therefore, there is an advantage in that it is possible to achieve both the normally-off and the high withstand voltage without making the density of a channel layer lower than that of a drift layer.

### BRIEF DESCRIPTION OF THE DRAWINGS

FIG. 1 is a cross sectional view schematically illustrating a JFET according to a first embodiment of the present invention;

FIG. 2 is a cross sectional view illustrating a conventional JFET;

FIG. 3A is a cross sectional view illustrating the JFET according to the first embodiment of the present invention in the order of manufacturing processes;

FIG. 3B is a cross sectional view illustrating the JFET according to the first embodiment of the present invention in the order of manufacturing processes;

FIG. 3C is a cross sectional view illustrating the JFET according to the first embodiment of the present invention in the order of manufacturing processes;

FIG. 3D is a cross sectional view illustrating the JFET according to the first embodiment of the present invention in the order of manufacturing processes;

FIG. 3E is a cross sectional view illustrating the JFET according to the first embodiment of the present invention in the order of manufacturing processes;

FIG. 3F is a cross sectional view illustrating the JFET according to the first embodiment of the present invention in the order of manufacturing processes;

FIG. 4 is a cross sectional view schematically illustrating a JFET according to a second embodiment of the present invention;

FIG. 5A is a cross sectional view illustrating the JFET according to the second embodiment of the present invention in the order of manufacturing processes;

FIG. 5B is a cross sectional view illustrating the JFET according to the second embodiment of the present invention in the order of manufacturing processes;

FIG. 5C is a cross sectional view illustrating the JFET according to the second embodiment of the present invention in the order of manufacturing processes;

FIG. 5D is a cross sectional view illustrating the JFET according to the second embodiment of the present invention in the order of manufacturing processes;

FIG. 5E is a cross sectional view illustrating the JFET according to the second embodiment of the present invention in the order of manufacturing processes;

FIG. 5F is a cross sectional view illustrating the JFET according to the second embodiment of the present invention in the order of manufacturing processes;

FIG. 6 is a cross sectional view illustrating a JFET according to a third embodiment of the present invention;

FIG. 7A is a cross sectional view illustrating the JFET according to the third embodiment of the present invention in the order of manufacturing processes;

FIG. 7B is a cross sectional view illustrating the JFET according to the third embodiment of the present invention in the order of manufacturing processes;

FIG. 7C is a cross sectional view illustrating the JFET according to the third embodiment of the present invention in the order of manufacturing processes;

FIG. 7D is a cross sectional view illustrating the JFET according to the third embodiment of the present invention in the order of manufacturing processes;

FIG. 7E is a cross sectional view illustrating the JFET according to the third embodiment of the present invention in the order of manufacturing processes;

FIG. 7F is a cross sectional view illustrating the JFET according to the third embodiment of the present invention in the order of manufacturing processes;

FIG. 8 is a cross sectional view illustrating a JFET according to a fourth embodiment of the present invention;

FIG. 9 is a cross-sectional view illustrating one of manufacturing processes of the JFET according to the fourth embodiment of the present invention;

FIG. 10 is a cross sectional view illustrating a JFET according to a fifth embodiment of the present invention;

FIG. 11 is a cross sectional view illustrating a JFET according to a sixth embodiment of the present invention;

FIG. 12 is a cross sectional view illustrating a JFET according to a seventh embodiment of the present invention;

FIG. 13 is a perspective view illustrating a plurality of individual JFETs according to an eighth embodiment of the present invention;

FIG. 14 is a perspective view illustrating the plurality of JFETs according to the eighth embodiment of the present invention;

FIG. 15 is a plan view illustrating a layout method of the JFETs according to the eighth embodiment;

FIG. 16 is a plan view illustrating a layout method of the JFETs at another level according to the eighth embodiment; and

FIG. 17 is a diagram illustrating an inverter that uses JFETs according to the eighth embodiment of the present invention.

### DESCRIPTION OF THE PREFERRED EMBODIMENTS

The undermentioned embodiments achieve the object of achieving both the high withstand voltage and the low on-resistance without applying a process of forming the trench side-wall oxidation film and a process of selectively removing the oxidation film on the trench bottom.

### First Embodiment

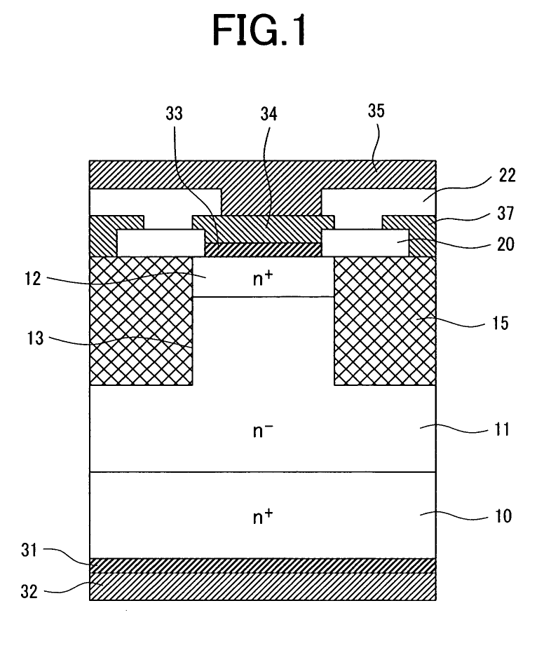

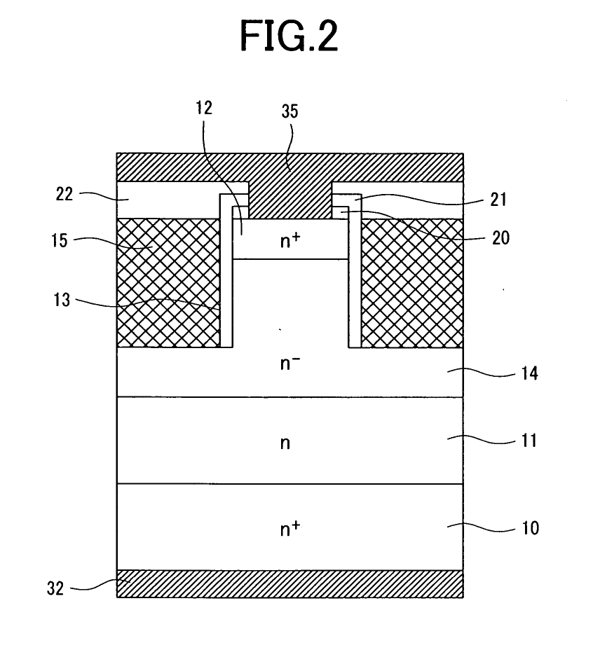

FIG. 1 is a cross sectional view illustrating a JFET according to a first embodiment of the present invention. Main elements of this embodiment will be described as below. An n− drift layer 11 and an n+ source layer 12 are laminated on an n+ —SiC substrate 10. A p-type polycrystalline Si layer is formed on each of the side walls of the n− drift layer 11 and on each of the side walls of the n+ source layer 12. In addition, a silicide electrode 33 which is an ohmic silicide layer used to form a low resistant contact is formed above the n− drift layer 11. Further, a source electrode 34 is formed on the top of the silicide electrode 33 so that the source electrode 34 is connected to a source pad 35. On the other hand, a drain electrode 32 is formed on the bottom of an n+ —SiC substrate 10 through a silicide electrode 31 that is an ohmic silicide layer used to form a low resistant contact. In addition, reference numeral 37 denotes a gate electrode. Incidentally, the gate electrode 37 is insulated from the silicide electrode 33 and the source electrode 34 by an insulating layer 20.

The structure according to this embodiment is characterized by the contact between a p-type polycrystalline Si 15 and the SiC not only on the trench bottom but also on the whole surface of the trench side wall 13. The density of the drift layer 11 is 2.0×10¹⁶ cm⁻³; the density of the polycrystalline Si 15 ranges from 10¹⁸ cm⁻³ to 10¹⁹ cm⁻³; and the width of a channel formed between pieces of the polycrystalline Si is 0.45 μm. As a result of forming a pn junction even on the whole surface of the channel side wall, a depletion layer extends over the whole channel. Accordingly, 600 V could be achieved in a normally-off state.

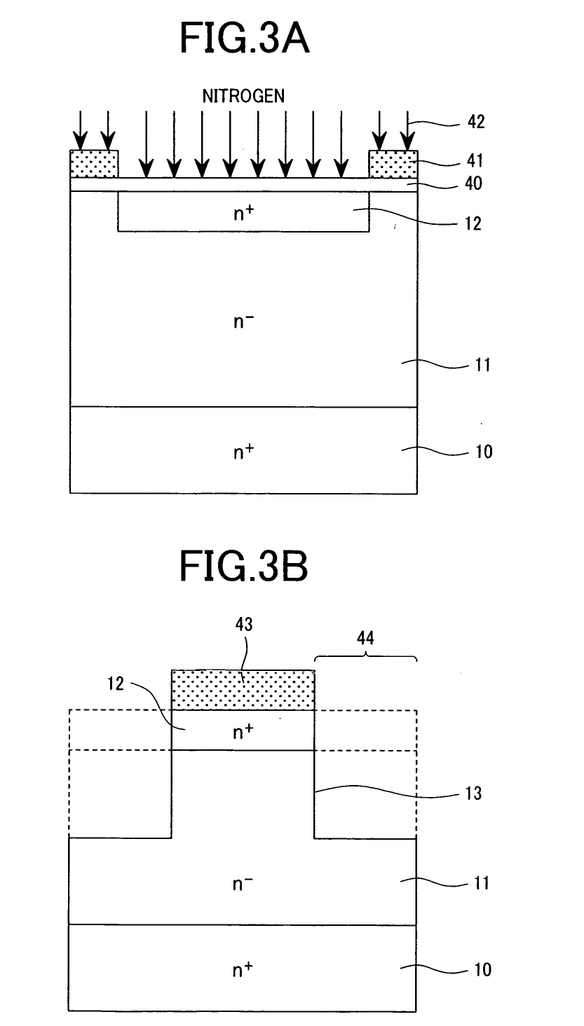

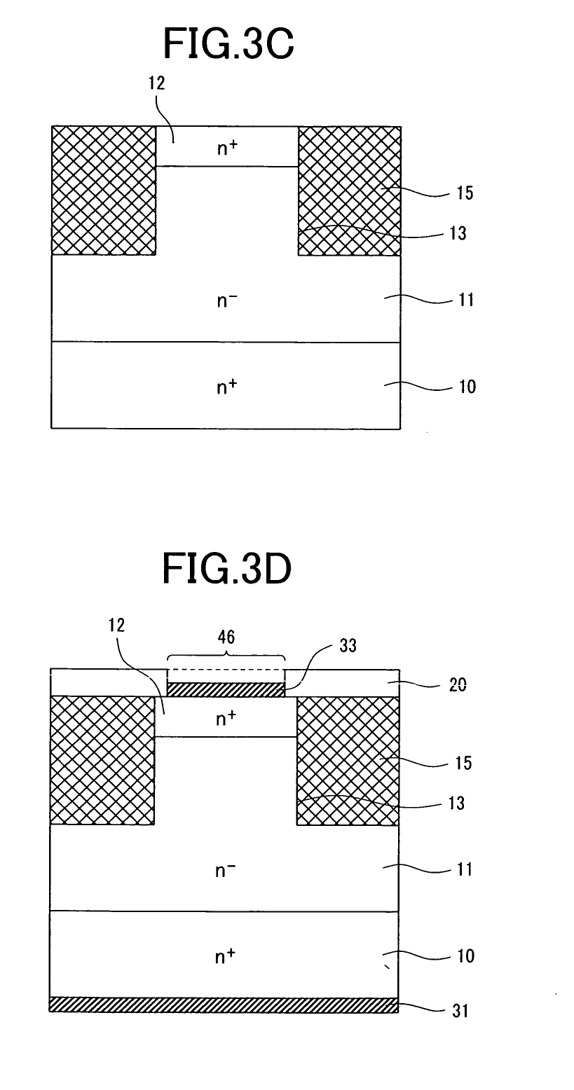

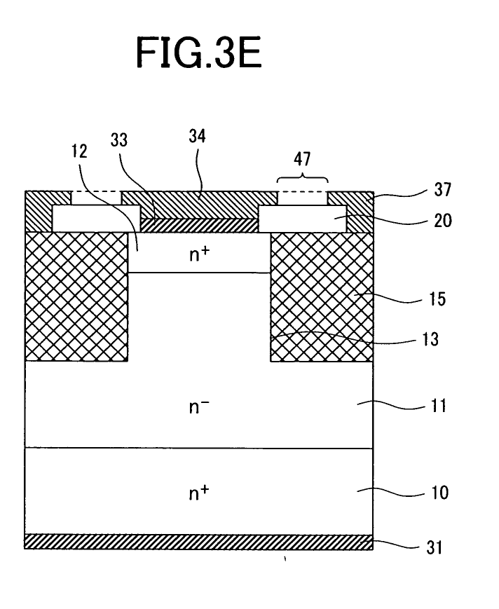

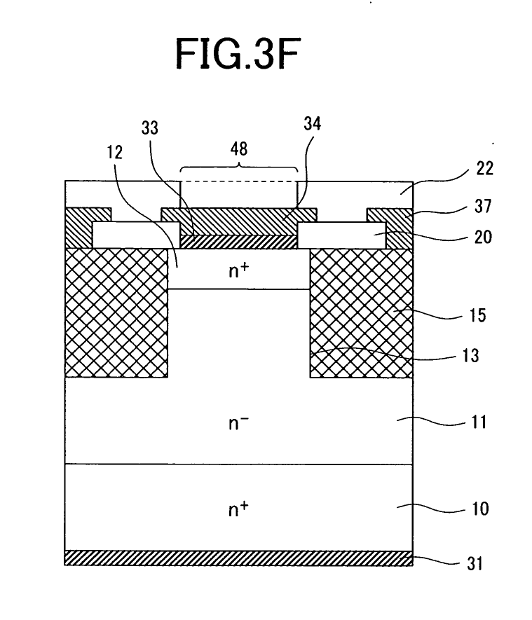

FIGS. 3A through 3F are diagrams each schematically illustrating a process of forming the JFET according to the first embodiment. Ion implantation of nitrogen 42 is performed so that an ion-implantation mask material 41 on oxidation film 40 is patterned on an n− layer 11 to form an n+ source 12 (process a: FIG. 3A). After the oxidation film 40 and the mask material 41 are removed, heat treatment is performed at 1700° C. to activate the nitrogen corresponding to the ion implantation. After the heat treatment, an etching mask material 43 such as oxidation film is formed on the n+ source 12. After the patterning, a trench 44 is formed by dry etching (process b: FIG. 3B). The p-type polycrystalline Si 15 is embedded in the trench 44 to perform planarization (process c: FIG. 3C). Oxidation film 20 used for dielectric isolation is formed on a surface of the n+ source 12; and an Ni layer 31 which is used as a drain electrode is formed on a surface of an n+ substrate 10 that is a drain. After that, a contact window 46 is formed on the surface of the n+ source 12 to form an Ni layer 33 that is used as a source electrode. Then, heat treatment is performed at 1000° C. so as to change the Ni layers 31, 33 into silicide (process d: FIG. 3D). After a gate contact window is formed on the oxidation film 20 of the polycrystalline Si 15, an Al electrode is formed, and an isolation region 47 is removed by means of etching to form a source Al electrode 34 and a gate Al electrode 37 (process e: FIG. 3E). Further, insulating film 22 used for source/gate dielectric isolation is formed so as to form a window 48 that is used to contact a source electrode for drawing (process f: FIG. 3F). Lastly, although not illustrated, as a result of forming the source electrode for drawing, the formation of the JFET according to the first embodiment shown in FIG. 1 is completed.

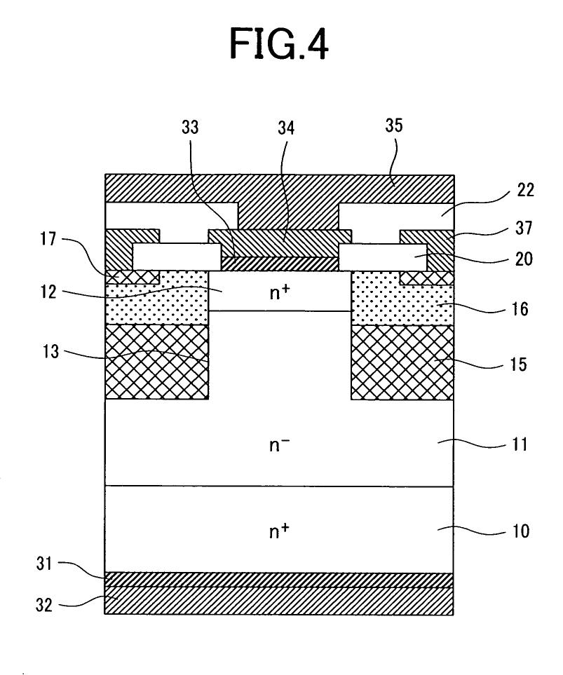

FIG. 4 is a cross sectional view illustrating a structure of a JFET according to a second embodiment of the present invention. In the first embodiment, the p-type polycrystalline Si having the uniform density is embedded in the whole trench. In order to improve the normally-off performance, it is desirable that the density of the embedded polycrystalline Si be high. On the other hand, in order to avoid malfunction at the time of switching, it is desirable that the negative voltage can be applied to a gate even in the normally-off state. Accordingly, it is necessary to ensure the withstand voltage whose value is several V or more between the source and the gate. For this reason, this embodiment is based on the assumptions that a low-density portion 16 is the side wall contacting the n+ source 12 of the embedded polycrystalline Si, and that a high-density portion 15 is located on the channel region side. This makes it possible to ensure the withstand voltage between the source and the gate, and to improve the normally-off performance. However, if the electrode directly contacts the p type low-density polycrystalline Si 16, the contact resistance increases. Therefore, this embodiment adopts a structure in which a p type high-density contact region 17 is partially formed in the low-density polycrystalline Si 16. Incidentally, parts similar to those shown in FIG. 1 are denoted by similar reference numerals.

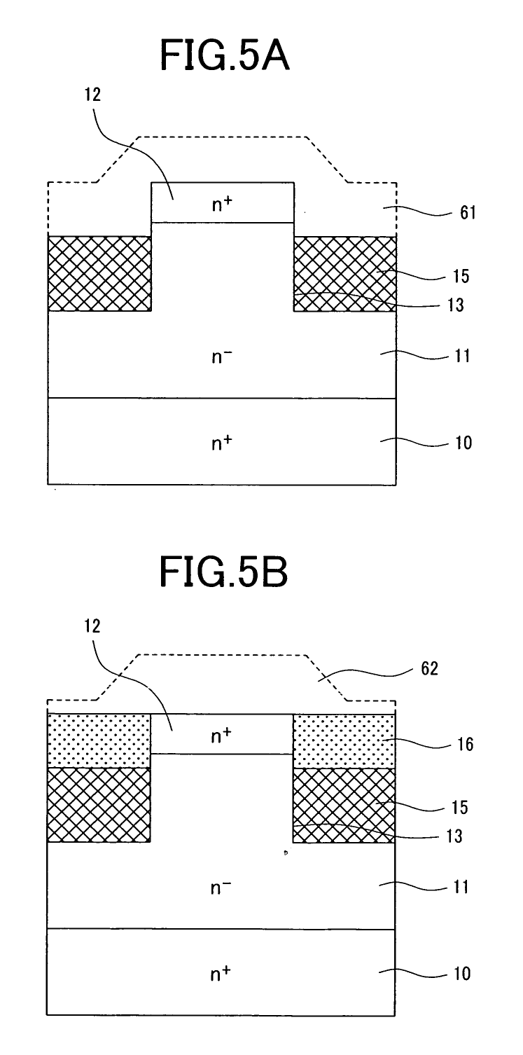

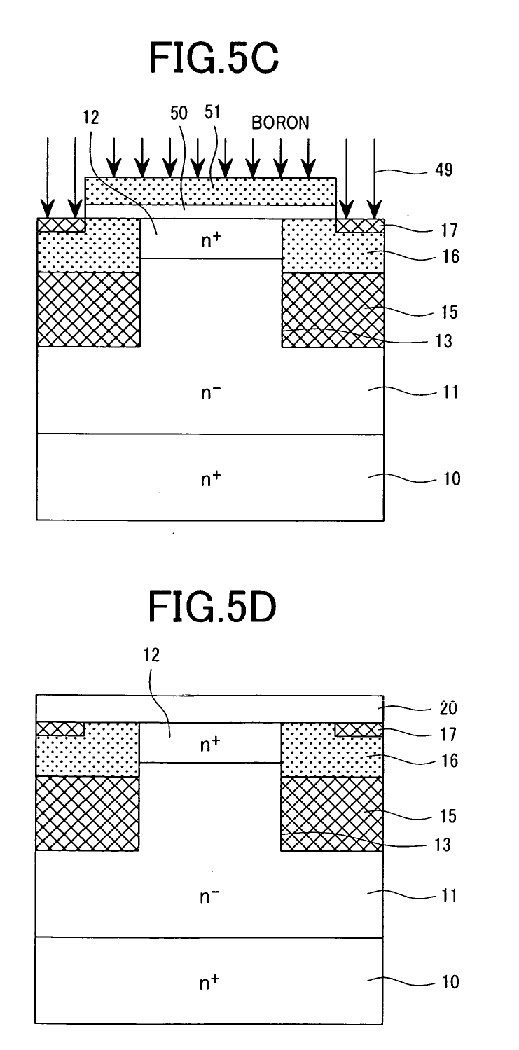

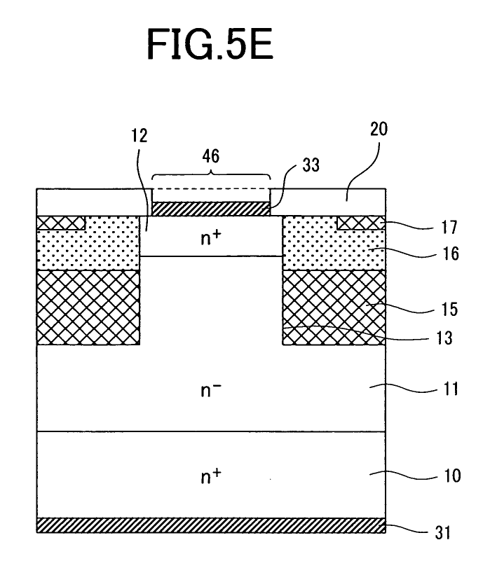

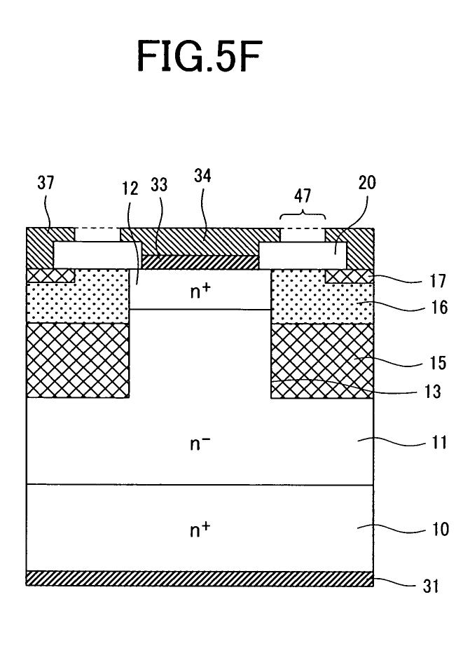

FIGS. 5A through 5F are diagrams each schematically illustrating a process of forming the JFET according to the second embodiment. At the time of the planarization of the high-density embedded polycrystalline Si 15 shown in FIG. 3C, the polycrystalline Si 15 is removed by means of over etching until the n+ source 12 is exposed (process a: FIG. 5A). Subsequently, the low-density polycrystalline Si 16 is formed to perform planarization (process b: FIG. 5B). Oxidation film 50 and an ion implantation mask 51 are formed on the surface, and then patterning is performed. Next, ion implantation of boron into the low-density polycrystalline Si 16 is performed to form the contact region 17 (process c: FIG. 5C). After the oxidation film 50 and the mask material 51 are removed, oxidation film 20 used for dielectric isolation is formed. The subsequent processes e (FIG. 5E) and f (FIG. 5F) are the same as those shown in FIG. 3. After the processes e and f, the formation of the JFET according to the second embodiment shown in FIG. 4 is completed.

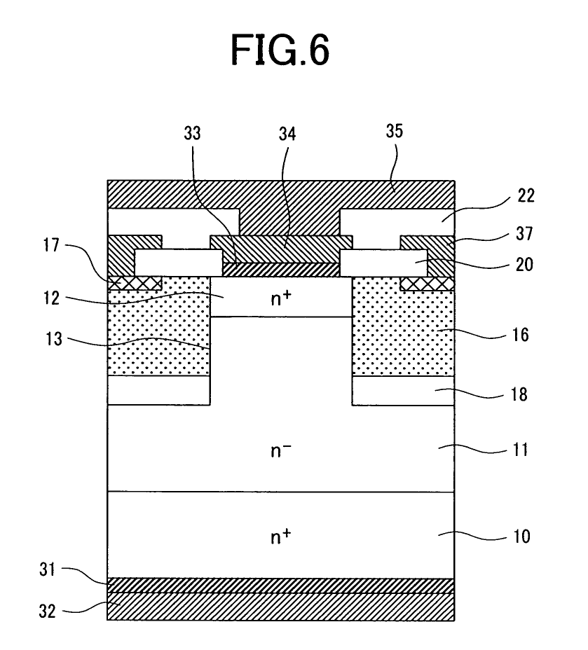

FIG. 6 is a cross sectional view illustrating a structure of a JFET according to a third embodiment of the present invention. In order to achieve the high withstand voltage by a pn junction of the p-type polycrystalline Si and the n-type SiC, a value ranging from the latter half of 10¹⁹ cm⁻³ up to the order of 10²⁰ cm⁻³ is required as the density of the polycrystalline Si. Under such circumstances, this embodiment adopts a structure in which the high withstand voltage is achieved at the polycrystalline Si density of the order of 10¹⁸ cm⁻³. Accordingly, the trench bottom is provided with a p-type SiC layer 18. The density of the p-type SiC layer 18 is 2×10 cm⁻³; and the thickness thereof is 0.3 μm. As a result, the depletion layer from the drain side of the n− drift layer 11 remains inside the p-type SiC layer 18. Therefore, a high electric field does not occur in the polycrystalline Si 16, and the high withstand voltage can be achieved.

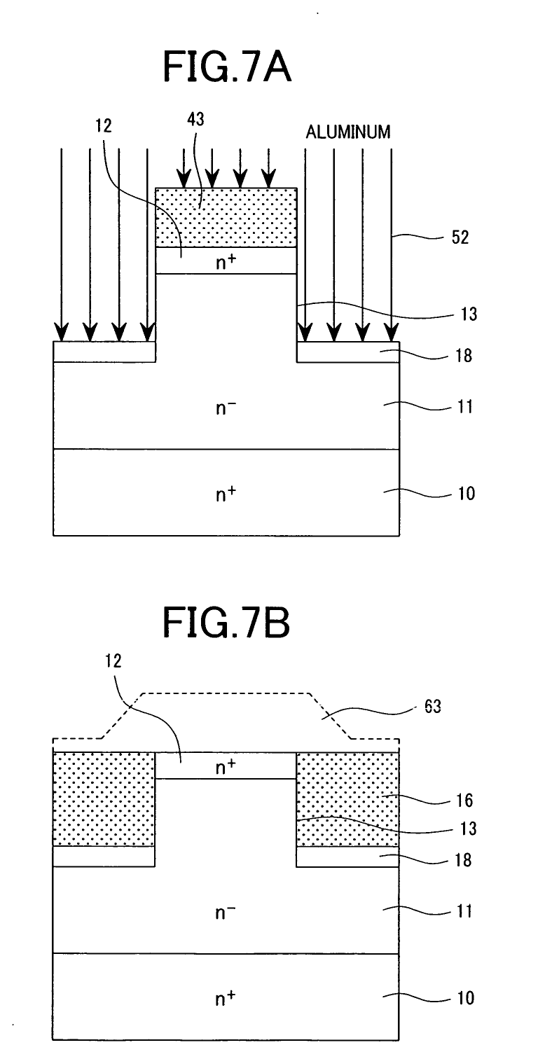

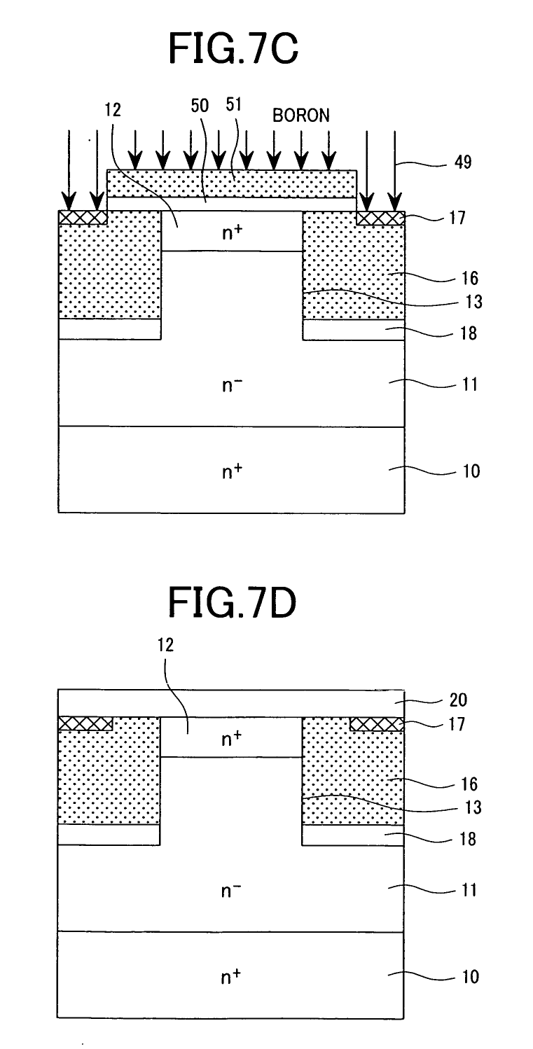

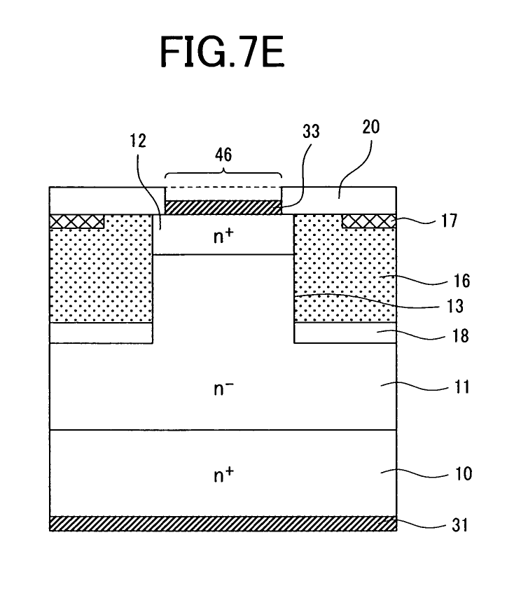

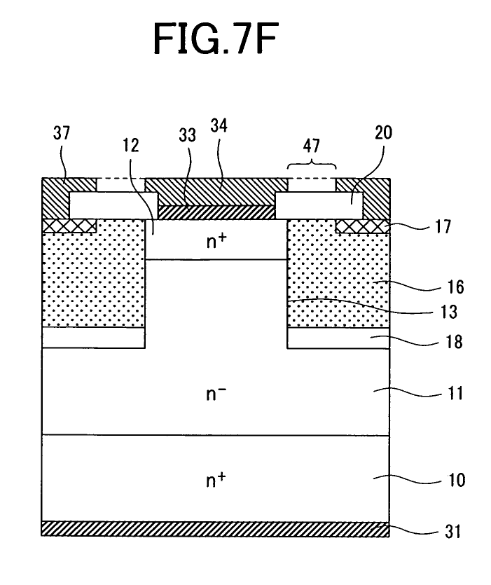

FIGS. 7A through 7F are diagrams each schematically illustrating a process of forming the JFET according to the third embodiment. After the trench shown in FIG. 3B is formed, ion implantation of Al is performed to form the p-type SiC layer 18 (process a: FIG. 7A). However, in this process, differently from the process of the first embodiment, activation heat treatment is not performed immediately after nitrogen ion implantation used for the formation of the n+ source. The activation heat treatment is performed after the process a. Next, after the p-type polycrystalline Si 16 is formed, planarization is performed (process b: FIG. 7B). The subsequent processes c (FIG. 7C) through f (FIG. 7F) are the same as the processes c (FIG. 5C) through f (FIG. 5f) in the second embodiment. After the processes c through f, the formation of the JFET according to the third embodiment shown in FIG. 6 is completed.

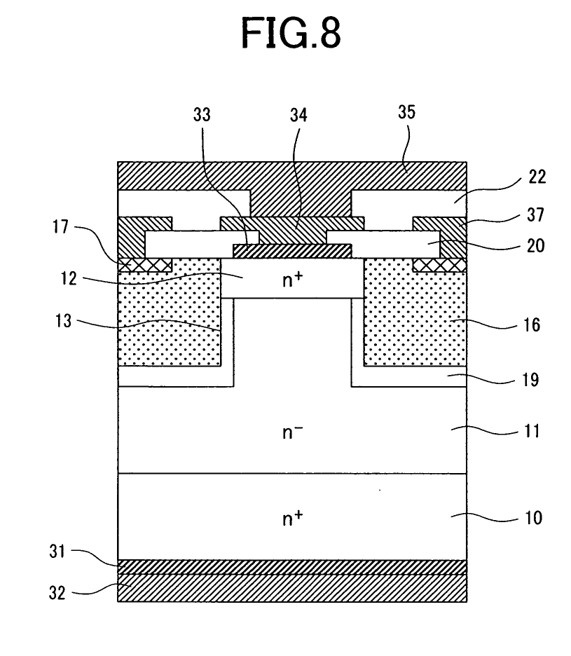

FIG. 8 is a cross sectional view illustrating a structure of a JFET according to a fourth embodiment of the present invention. Since a band gap of the polycrystalline Si is narrower than that of SiC, if a pn junction with SiC is formed, the built-in voltage becomes lower than about 2.5 V, which is the built-in voltage at the pn junction of single SiC. Normally-off type devices control on-off operation at a value ranging from 0 V to the built-in voltage. Therefore, in the case of the SiC junction FET that uses a polycrystalline Si gate, an allowable range of the gate voltage magnitude becomes narrow, which is a problem to be solved. Accordingly, this embodiment adopts a structure in which a p-type SiC region 19 is formed both on the trench side wall 13 and on the bottom of the trench so that the p-type polycrystalline Si 16 is embedded in the trench. As a result, the built-in voltage becomes the same as that of the single SiC JFET. Accordingly, it is possible to prevent the gate voltage magnitude from decreasing.

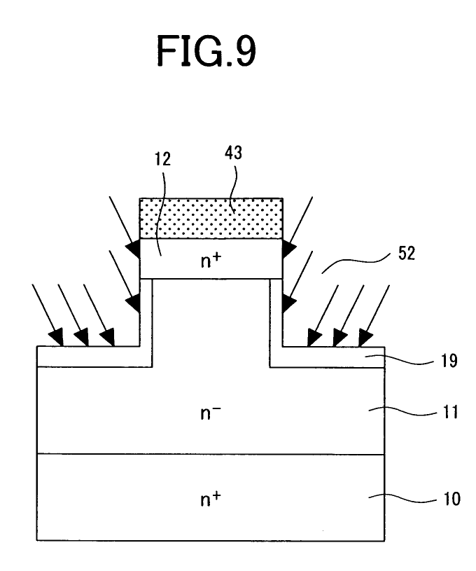

FIG. 9 is a diagram schematically illustrating part of the process of forming the JFET according to the fourth embodiment. In FIG. 7A illustrating part of the JFET process according to the third embodiment, vertical ion implantation is performed, whereas oblique ion implantation 52 is performed in this process. This makes it possible to form the p-type SiC region 19 both on the trench side wall and on the bottom of the trench. The other processes are the same as those shown in FIGS. 7B through 7F.

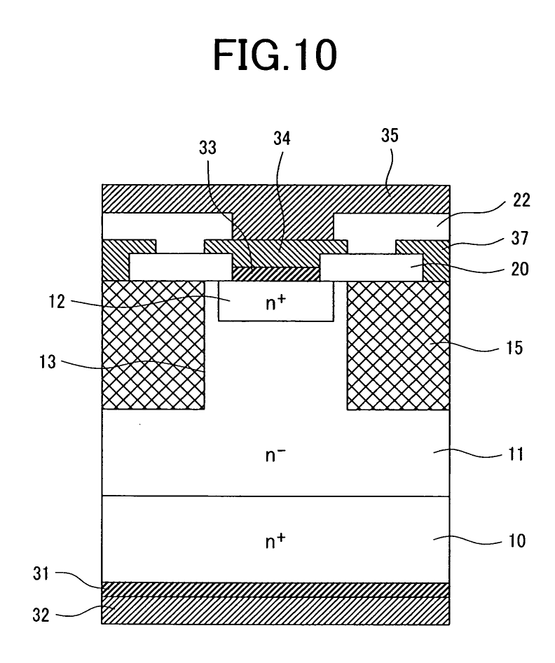

FIG. 10 is a cross sectional view illustrating a structure of a JFET according to a fifth embodiment of the present invention. In order to ensure the withstand voltage between the source and the gate, this embodiment adopts a structure in which an n− region 11 exists between the trench side wall 13 and the n+ source 12. In addition to it, the density of the p-type polycrystalline Si 15 is set to 10²⁰ cm⁻³. As a result, it is possible to ensure the withstand voltage between the source and the gate, whose value is 20 V or more, and also to achieve the high withstand voltage and the low on-resistance.

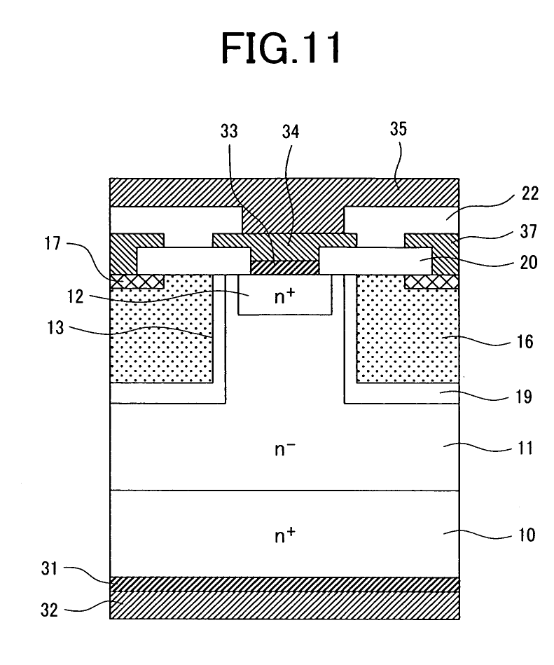

FIG. 11 is a cross sectional view illustrating a structure of a JFET according to a sixth embodiment of the present invention. This embodiment adopts a structure in which an n− region 11 exists between the p-type SiC region 19 of the trench side wall and the n+ source 12 in the JFET of the fourth embodiment. As a result, it is possible to ensure the withstand voltage between the source and the gate, whose value is 20 V or more, and to achieve the high withstand voltage and the low on-resistance, and also to prevent the gate voltage magnitude from decreasing.

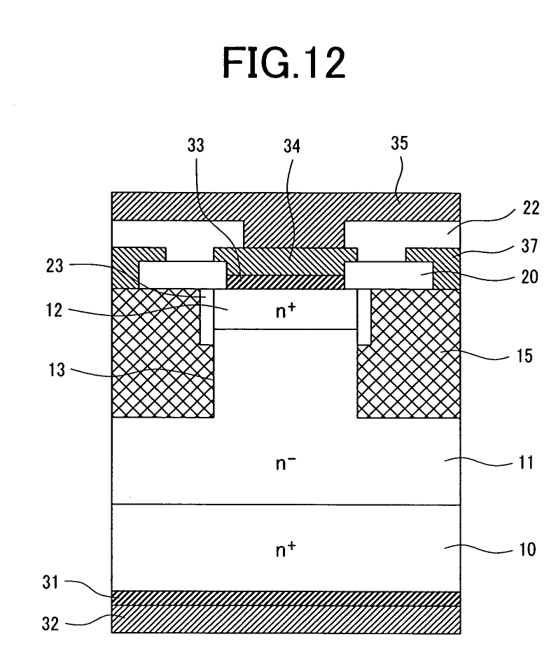

FIG. 12 is a cross sectional view illustrating a structure of a JFET according to a seventh embodiment of the present invention. In this embodiment, a structure in which oxidation film 23 is formed on the trench side wall 13 of the n+ source 12 is adopted. On the other hand, oxidation film is not formed in a large part of the trench side wall 13 in a c channel region, and accordingly the trench side wall 13 directly contacts the p-type polycrystalline. As a result, it is possible to ensure the withstand voltage between the source and the gate, whose value is 20 V or more, and also to achieve both the high withstand voltage and the low on-resistance.

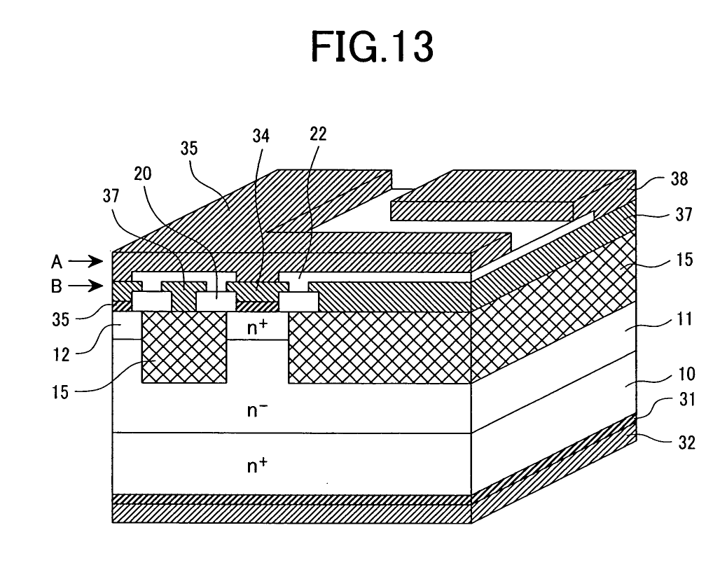

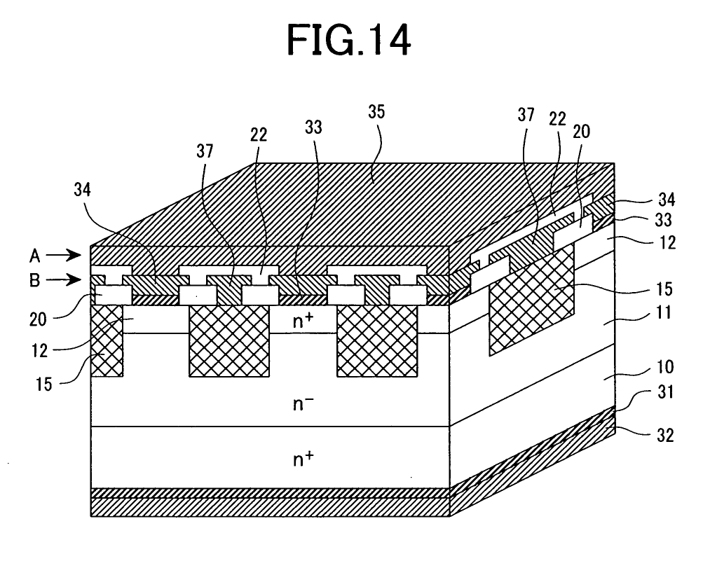

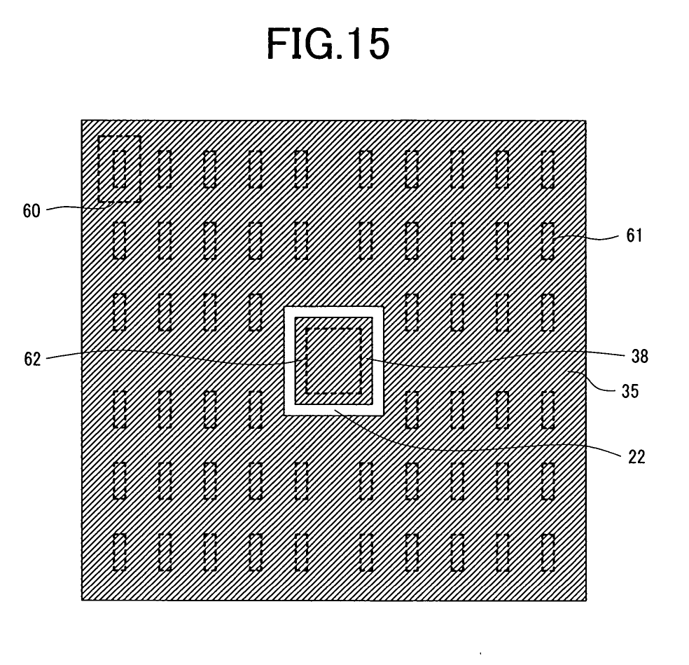

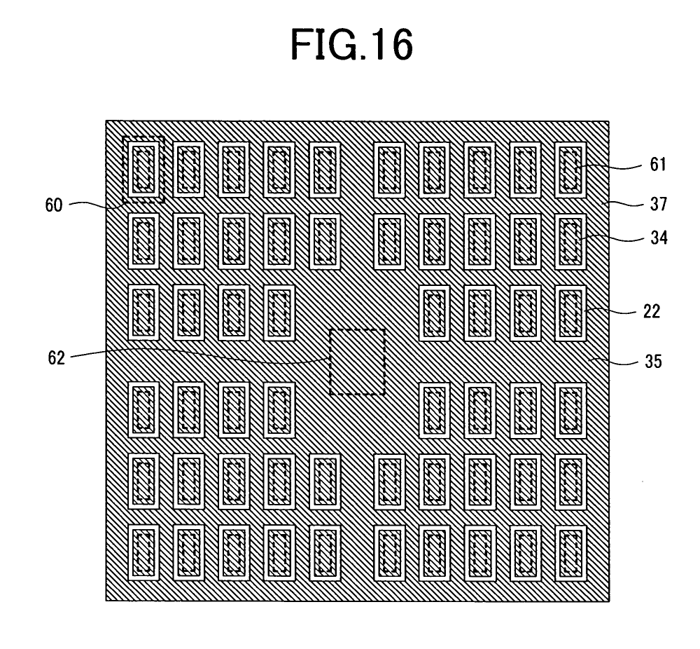

FIGS. 13 and 14 are perspective views each schematically illustrating an example of a JFET structure according to the present invention. As an example, the JFET in the first embodiment is described. However, the JFETs in the other embodiments can also be similarly used for the description. Through each individual source Al electrode 34, a plurality of n+ sources 12 contacts a common source pad 35 that is formed of metal film such as Al. FIG. 15 is a layout drawing taken along the depth indicated by reference numeral A shown in FIGS. 13 and 14. A rectangle indicated by reference numeral 61 corresponds to a contact portion between each individual source Al electrode 34 and the source pad 35 shown in FIGS. 13 and 14. FIG. 16 is a layout drawing taken along the depth indicated by reference numeral B shown in FIGS. 13 and 14. The gate Al electrodes 37 are connected to one another, and contact a common gate pad 38 in a quadrangular area indicated by reference numeral 62. In FIGS. 15 and 16, a rectangle 60 indicated with a dash-dot line is each individual JFET shown in each embodiment. These JFETs are placed at regular intervals. However, with the objective of reducing the wiring resistance of the gate, unit JFETs 60 is not always placed on the whole surface. An area whose gate line width is wide is provided. Such a layout structure enables a large number of individual JFETs to operate concurrently and equally.

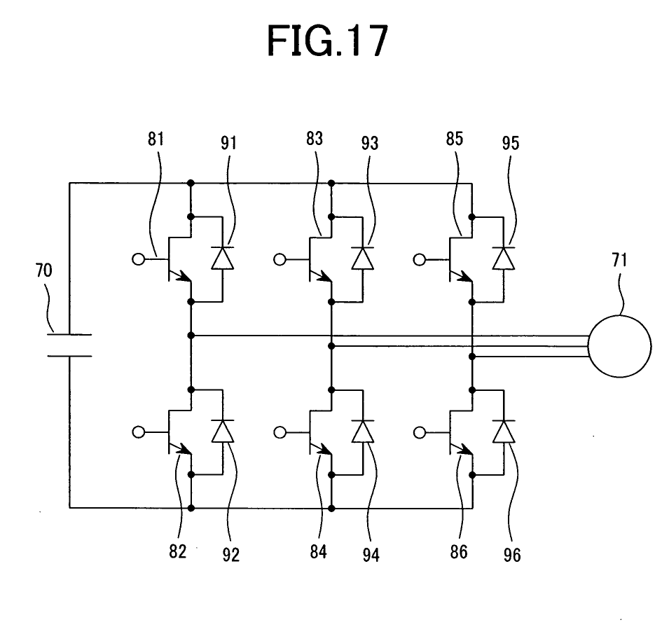

FIG. 17 is a diagram illustrating an example of an inverter circuit that uses JFETs according to the present invention. In the figure, reference numeral 70 denotes a capacitor that is the direct-current power supply; reference numeral 71 denotes a load such as a motor; reference numerals 81 through 86 denote JFETs according to the present invention; and reference numeral 91 through 96 denote free wheel diodes used for reflux. Since the JFETs according to the present invention are characterized by both the high withstand voltage and the low on-resistance, it is possible to reduce the volume of the inverter having the circuit configuration shown in FIG. 17. Moreover, as a result of producing an inverter for the supply voltage 200 V by use of JFETs each having a withstand voltage of 600 V, the volume of the inverter could be reduced to a half of the volume for the case where Si devices are used.

According to the present invention, since the density of a channel layer becomes the same as that of a drain layer, the processes become simple, which is an effect achieved by the present invention. In addition, since it is possible to increase the normally-off performance, and since it is possible to achieve both the low gate resistance and the high gate withstand voltage, there is an effect of being superior in usability.

Up to this point, the present invention was described in detail. Main modes of the present invention will be listed as below.

(1) In a junction FET in which first conductivity type high-density SiC is formed as a drain layer; first conductivity type low-density SiC connecting the drain layer is formed as a drift layer; first conductivity type high-density SiC which is formed on the drift layer is used as a source layer; part of the drift layer is used as a channel region by forming a trench from the source layer up to a position having the specified depth of the drift layer; and a second conductivity type Si with which the trench is filled is used a gate region, at least a side wall of the channel region contacts the Si gate region without using oxidation film.

(2) In a junction FET in which first conductivity type high-density SiC is formed as a drain layer; first conductivity type low-density SiC connecting the drain layer is formed as a drift layer; first conductivity type high-density SiC which is formed on the drift layer is used as a source layer; part of the drift layer is used as a channel region by forming a trench from the source layer up to a position having the specified depth of the drift layer; and a second conductivity type Si with which the trench is filled is used a gate region, the density of the Si gate region, which contacts substantially the whole side wall of the channel region without using oxidation film, is made high, the density of the Si gate region, which contacts the side wall of the source region without using oxidation film, is made low, and a high-density Si region is formed on a surface of the low-density Si gate region.

(3) In a junction FET in which first conductivity type high-density SiC is formed as a drain layer; first conductivity type low-density. SiC connecting the drain layer is formed as a drift layer; first conductivity type high-density SiC which is formed on the drift layer is used as a source layer; part of the drift layer is used as a channel region by forming a trench from the source layer up to a position having the specified depth of the drift layer; and a second conductivity type Si with which the trench is filled is used a gate region, at least the side wall of the channel region contacts the Si gate region without using oxidation film, and a second conductivity type region is formed in SiC located on the bottom of the trench.

(4) In a junction FET in which first conductivity type high-density SiC is formed as a drain layer; first conductivity type low-density SiC connecting the drain layer is formed as a drift layer; first conductivity type high-density SiC which is formed on the drift layer is used as a source layer; part of the drift layer is used as a channel region by forming a trench from the source layer up to a position having the specified depth of the drift layer; and a second conductivity type Si with which the trench is filled is used a gate region, at least the side wall of the channel region contacts the Si gate region without using oxidation film, and a second conductivity type region is formed in SiC located on the bottom of the trench and on the side wall of the trench of the channel region.

(5) In the preceding paragraph (1), oxidation film is formed between the side wall of the source region and the Si gate region.

(6) An electric circuit that uses the junction FET described in the preceding paragraphs (1) through (5).

What is claimed is:

1. A junction FET comprising:
a drain layer formed of first conductivity type SiC;
a drift layer formed of first conductivity type SiC whose impurity density is lower than that of the first conductivity type SiC forming the drain layer, the drift layer contacting the drain layer;
a source layer formed of first conductivity type SiC whose impurity density is higher than that of the first conductivity type SiC forming the drift layer, the source layer being formed on a surface of the drift layer that is opposite to the surface contacted with the drain layer;
a concave portion that is formed from the source layer up to the drift layer, the concave portion reaching the specified depth of a semiconductor layered product; and
a second conductivity type Si layer with which the concave portion is filled, the second conductivity type Si layer contacting each of both side walls of the semiconductor layered product ranging from the source layer up to the drift layer;
wherein:
the second conductivity type Si layer is a gate region; and
a channel region is formed in the drift layer.

2. The junction FET according to claim 1, wherein:
the second conductivity type Si layer that forms the gate region is a polycrystalline Si layer.

3. The junction FET according to claim 1, wherein:
the Si gate region includes at least two regions, each of which has an impurity density different from that of the other regions, in a lamination direction;
the density of the Si gate region contacting the side wall of the source region is lower than that of the other regions; and
the low-density Si gate region includes a high-density Si region on the upper side of the semiconductor layered product in the lamination direction.

4. The junction FET according to claim 1, wherein:
a second conductivity type SiC region is formed on the drift layer side of the second conductivity type Si layer that contacts the semiconductor layered product ranging from the source layer up to the drift layer.

5. The junction FET according to claim 2, wherein:
a second conductivity type SiC region is formed on the drift layer side of the second conductivity type Si layer that contacts the semiconductor layered product ranging from the source layer up to the drift layer.

6. The junction FET according to claim 1, wherein:
a second conductivity type SiC region is formed on the drift layer side in the second conductivity type Si layer that contacts the semiconductor layered product ranging from the source layer up to the drift layer.

7. The junction FET according to claim 1, wherein:
an insulating film is formed between the side wall of the source region and the Si gate region.

8. A junction FET, a specified substrate being equipped with the junction FETs as at least first and second junction FETs, the junction FET comprising:
a drain layer formed of first conductivity type SiC;
a drift layer formed of first conductivity type SiC whose impurity density is lower than that of the first conductivity type SiC forming the drain layer, the drift layer contacting the drain layer;
a source layer formed of first conductivity type high-density SiC, the source layer being formed on a surface of the drift layer that is opposite to the surface contacted with the drain layer;
a concave portion that is formed from the source layer up to the drift layer, the concave portion reaching the specified depth of a semiconductor layered product; and
a second conductivity type Si layer with which the concave portion is filled, the second conductivity type Si layer contacting each of both side walls of the semiconductor layered product ranging from the source layer up to the drift layer;
wherein:
the second conductivity type Si layer is a gate region;
a channel region is formed in the drift layer; and
each of the first and second junction FETs includes a metallic layer through which the second conductivity type Si layer of each of the first and second junction FETs electrically connects a gate region.
